(19) United States
(12) Patent Application Publication
(10) Pub. No.: US 2013/0204552 A1
(43) Pub. Date: Aug. 8, 2013

(54) METHOD AND APPARATUS FOR DETECTING DEVICE ANOMALY

(71) Applicants: Chung-Wei Lin, Changhua City (TW); Lun-Chia Kuo, Taichung (TW); Yu-Jung Yeh, Zhubei City (TW); Jen-Hsiao Wen, Taichung (TW)

(72) Inventors: Chung-Wei Lin, Changhua City (TW); Lun-Chia Kuo, Taichung (TW); Yu-Jung Yeh, Zhubei City (TW); Jen-Hsiao Wen, Taichung (TW)

(73) Assignee: INDUSTRIAL TECHNOLOGY RESEARCH INSTITUTE, Hsinchu (TW)

(21) Appl. No.: 13/494,857

(22) Filed: Jun. 12, 2012

(30) Foreign Application Priority Data
Feb. 8, 2012 (TW) 101104110

(51) Int. Cl. G06F 19/00; G01R 31/14

(52) U.S. Cl. 702/58; 324/511

(57) ABSTRACT

A method and an apparatus for detecting device anomaly are provided. The apparatus including a database configured to store a plurality of electric power features; a measurement module configured to measure electric power of a device to generate electric power information; a judgment module connected to the database and the measurement module, configured to judge whether the device is abnormal based on the plurality of electric power features and the electric power information; and a detection module connected to the judgment module, configured to detect operation states of a plurality of elements in the device to generate a plurality of state signals when the judgment module judges that the device is abnormal; wherein, the judgment module further judges whether each element of the plurality of elements is abnormal based on the plurality of state signals, the electric power information, and the plurality of electric power features.

### CROSS-REFERENCE TO RELATED APPLICATIONS

This non-provisional application claims priority under 35 U.S.C. §119(a) on Patent Application No(s). 101104110 filed in Taiwan, R.O.C. on Feb. 8, 2012, the entire contents of which are hereby incorporated by reference.

### BACKGROUND

1. Technical Field

The disclosure relates to a method and an apparatus for detecting anomaly, more particularly to a method and apparatus for detecting device anomaly.

2. Related Art

Generally, anomaly of electric device during operation is founded by people's active notice. However, most devices are working based on power source supply, and people are not always stand beside the devices and monitor the devices. Therefore, if a device is in abnormal operation without people standing nearby, the anomaly cannot be founded in time for taking appropriate actions. As a result, a huge loss may be caused. Furthermore, a few elements in a device may be in abnormal operation with time.

For example, valves anomaly or shockproof sheet aging may occur in the compressor of an air conditioner, and the rotor or bearing in a motor may be worn and torn. An element anomaly may result in much more power consumption of the device or accidents. Currently, people cannot know which element is in abnormal operation or take actions in real time. Thus, a mechanism for efficiently detecting device anomaly is needed to facilitate check and repair.

### SUMMARY

In one aspect, an apparatus for detecting device anomaly comprises a database configured to store a plurality of electric power features; a measurement module configured to measure electric power of a device to generate electric power information; a judgment module connected to the database and the measurement module, configured to judge whether the device is abnormal based on the plurality of electric power features and the electric power information; and a detection module connected to the judgment module, configured to detect operation states of a plurality of elements in the device to generate a plurality of state signals to the judgment module; wherein, the judgment module further judges whether each element of the plurality of elements is abnormal based on the plurality of state signals, the electric power information, and the plurality of electric power features.

In another aspect, a method for detecting device anomaly comprises measuring electric power of a device to generate electric power information; obtaining a plurality of electric power features; judging whether the device is abnormal based on the electric power information and the plurality of electric power features; and if it is judged that the device is abnormal, detecting operation states of a plurality of elements of the device to generate a plurality of state signals, and judging whether each element of the plurality of elements is abnormal based on the electric power information and the plurality of electric power features.

In yet another aspect, an apparatus for detecting device anomaly comprises: a database, configured to store a plurality of electric power features; a measurement module configured to measure electric power of a plurality of home appliances in a device to generate electric power information; a judgment module connected to the database and the measurement module, configured to detect whether the plurality of home appliances in the device is abnormal based on the electric power features and the electric information; and a detection module connected to the judgment module, configured to detect operation states of the plurality of home appliances in the device to generate a plurality of state signals when the judgment module judges that the device is abnormal; wherein, the judgment module further judges whether each of the plurality of home appliances is abnormal based on the plurality of state signals, the electric information, and the electric power features.

In yet another aspect, a method for detecting device anomaly comprises: measuring electric power of a plurality of home appliances in a device to generate electric information; obtaining a plurality of electric power features; judging whether the plurality of home appliances are abnormal based on the electric information and the plurality of electric power features; and if it is judged that the device is abnormal, detecting operation states of the plurality of home appliances to generate a plurality of state signals, and judging whether each of the plurality of home appliances is abnormal based on the plurality of state signals, the electric information, and the plurality of electric features.

### BRIEF DESCRIPTION OF THE DRAWINGS

The present disclosure will become more fully understood from the detailed description given herein below for illustration only, and thus are not limitative of the present disclosure, and wherein:

FIG. 1 is a block diagram of an apparatus for detecting device anomaly based on an embodiment of the disclosure;

FIG. 2 is a block diagram of an apparatus for detecting device anomaly based on an embodiment of the disclosure;

FIG. 3 a block diagram of an apparatus for detecting device anomaly based on an embodiment of the disclosure;

FIG. 4 is a flowchart of a method for detecting anomaly based on an embodiment of the disclosure;

FIG. 5is a flowchart of a method for detecting anomaly based on an embodiment of the disclosure;

FIG. 6 is a flowchart of a method for detecting anomaly based on an embodiment of the disclosure; and

FIG. 7 is a flowchart of a method for detecting anomaly based on an embodiment of the disclosure.

### DETAILED DESCRIPTION

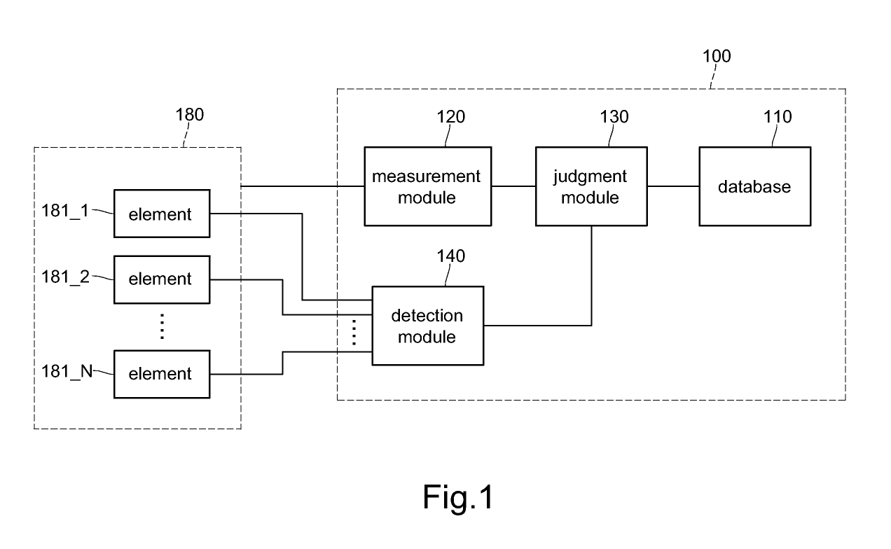

FIG. 1 is a block diagram of an apparatus for detecting device anomaly based on an embodiment of the disclosure. In this embodiment, the apparatus 100 configured to detect device anomaly is adapted to detect the operation state of the device 180. The device 180 may be an air conditioner, a generator, and so on. The device 180 comprises a plurality of elements 181_1˜181_N, where N is a positive integer. The apparatus 100 comprises a database 110, a measurement module 120, a judgment module 130, and a detection module 140.

The database 110 is configured to store various electric power features, which may include real power, reactive power, average current, relative standard deviation, but the disclosure is not limited this way. These features can be corrected or updated in process.

The measurement module 120 is configured to measure the electric power of the device 180 to generate electric power information. The measurement module 120 may be a power meter for measuring the current, voltage, or power of the device 180 in order to output electric power information regarding the current, voltage, or power.

The judgment module 130 connected to the database 110 and the measurement module 120 is configured to receive the electric power information outputted from the measurement module 120 aw well as the electric power features stored in the database 110. Based on the electric power information and the electric power features stored in the database 110, the judgment module 130 judges whether the device 180 is abnormal. Particularly, the judgment module 130 compares the electric power information outputted from the measurement module 120 with the electric power features stored in the database 110, and thus judges whether the device 180 is abnormal.

In this embodiment, since electric power information measured each time by the measurement 120 may be different, the judgment module 130 presets a range to judge whether the device 180 is abnormal. In this embodiment, the judgment module 130 utilizes for example a normal distribution (68-95-99.7 rule) to judge whether the difference between the electric power information outputted from the measurement module 120 and the electric power features stored in the database 110 falls in the range. For example, if the difference falls in the range, the judgment module 130 judges that the device 180 is not abnormal. If the difference does not fall in the range, the judgment module 130 judges that the device 180 is abnormal.

The detection module 140 connected to the judgment module 130 is configured to detect operation states of elements 181_1˜181_N in the device 180 if the judgment module 130 judges the device 180 to be abnormal, and the detection module 140 generates multiple state signals and sends these state signals to the judgment module 130. For example, the detection module 140 respectively sends a signal to each of the elements 181_1˜181_N. If the element (i.e. one of the elements 181_1˜181_N) receiving the signal is in normal operation, the element returns a corresponding signal to the detection module 140 and the detection module 140 generates a state signal with high logic level. Alternatively, if the element receiving the signal is not working or in abnormal operation, the element returns a corresponding signal to the detection module 140 and the detection module 140 generates a state signal with low logic level.

Then, the judgment module 130 judges whether each of the elements 181_1˜181_N is normal or abnormal based on the state signal, the electric power information, and the electric power features. Specifically, if the state signal is at high logic level and the electric power information is in accordance with the electric power features, the one of the elements 181_1˜181_N is normal. If the state signal is at low logic level, or the state signal is at high logic level but the electric power information is not in accordance with the electric power features, the one of the elements 181_1˜181_N is abnormal. As a result, the apparatus 100 in this embodiment can not only know whether the device 180 is abnormal, but also know which element of the elements 181_1˜181_N is abnormal. Therefore, the apparatus 100 can accelerate detecting the device 180's anomaly and facilitate check and repair.

In this embodiment, the database 110, the measurement module 120, the judgment 130, and the detection module 140 can be integrated in the apparatus 100, and the apparatus 100 can be disposed in the device 180 in order to detect the device 180's anomaly.

In another embodiment, the measurement module 120 and the detection module 140 may be disposed in the device 180 while the database 110 and the judgment module 130 may be disposed in the apparatus 100. Furthermore, the measurement module 120 and the detection module 140 may send the electric power information and state signals to the judgment module 130 by way of wired or wireless (WIFI, WIMAX, RF (Radio Frequency), PLC (Power Line Communication)) communication in order to judge whether the device 180 and any one of the elements 181_1˜181_N are normal or abnormal.

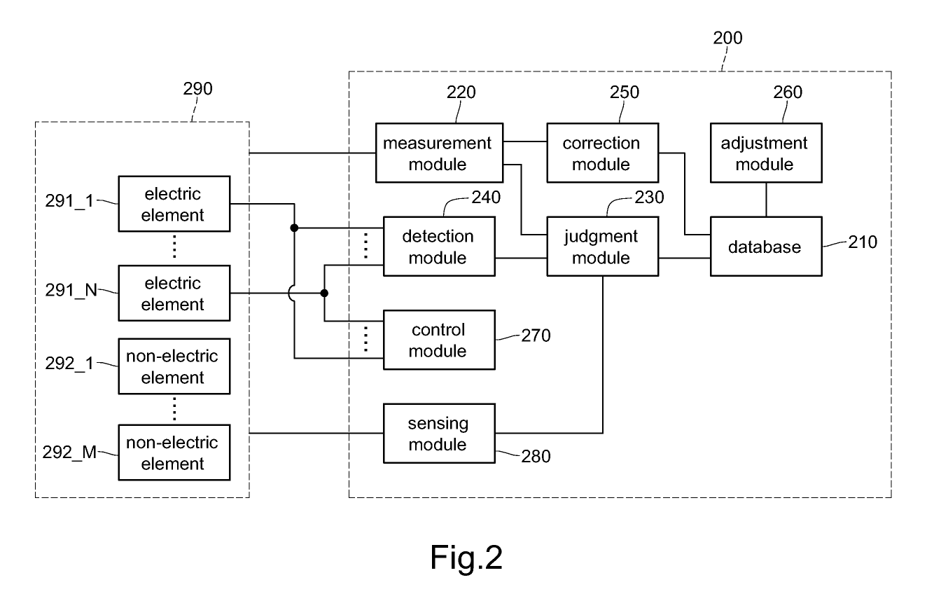

FIG. 2 is a block diagram of an apparatus for detecting device anomaly based on another embodiment of the disclosure. In this embodiment, the device 290 comprises a plurality of electric elements 291_1˜291_N (which may correspond to those in FIG. 1) and a plurality of non-electric elements 292_1˜292_M, where M is a positive integer. If the device 290 is an air conditioner, the electric elements 291_1˜291_N may be motors, compressors, and so on, while the non-electric elements 292_1˜292_M may be strainers, capillary tubes, and so on. The apparatus 200 includes a database 210, a measurement module 220, a judgment module 230, a detection module 240, a correction module 250, an adjustment module 260, a control module 270, and a sensing module 280. The operation of the database 210, the measurement module 220, the judgment module 230, and the detection module 240 may be referred to that of the database 110, the measurement module 120, the judgment module 130, and the detection module 140 in FIG. 1, and thus it will not be described again.

The correction module 250 connected to the measurement module 220 and the database 210 is configured to correct and update the electric power features in the database 210 based on the electric power information generated by the measurement module 120 and the electric power features preset in the database 210. For example, the correction module 250 obtains the relevance between the electric power information and the electric power features by way of least square error (LSE), generates a correction value for correcting the electric power features, and writes the correction value into the database 210. Therefore, the apparatus 200 can be adapted for different types of the device 290.

In addition, the adjustment module 260 connected to the database 210 and the measurement module 220 is configured to adjust the electric power information and the electric power features based on an environment condition. The environment condition may be but is not limited to be ambient temperature or variable voltage. For example, the adjustment module 260 may use interpolation technique to dynamically adjust the electric power features based on an ambient temperature. Moreover, the adjustment module 260 may use normalization technique to dynamically adjust the electric power information based on a variable voltage.

Before the judgment module 230 compares the electric power information with the electric power features, the adjustment module 260 dynamically adjusts the electric power information and the electric power features in order to reduce error detection of device anomaly.

The control module 270 is configured to generate multiple control signals to control operation states of the elements in the device 290. The operation states of the elements in the device 290 have various combinations. In this embodiment, the control module 270 sends multiple control signals to control each element (for example, electric elements 291_1˜291_N) to work or not to work. For example, the device 290 has three electric elements, A, B, and C. The combinations for operation states of A, B, and C are shown in the following table 1. In the table 1, “ON” represents on-operation, and “OFF” represents off-operation.

TABLE 1

| | | Electric Element |
|---|---|---|
| Electric Element A/Home | Electric Element | C/Home |
| Appliance D | B/Home Appliance E | Appliance F |
| ON | ON | ON |
| OFF | ON | ON |
| OFF | OFF | ON |
| ON | OFF | ON |
| ON | ON | OFF |
| OFF | ON | OFF |
| OFF | OFF | OFF |
| ON | OFF | OFF |

Based on the combinations as shown in table 1, the detection module 240 detects each combination by way of polling to generate multiple state signals corresponding to these combinations. Then, the judgment module 230 sequentially judges whether each element is normal or abnormal based on corresponding state signals, electric power information, and electric power features. Therefore, a statistical chart can be established and stored in the database 210.

For example, when the control module 270 controls all elements A, B, and C are “ON”, state signals received by the judgment module 230 are all at high logic level, for example, H, H, and H. Then, the judgment module 230 can obtain the electric power features corresponding to each combination in table 1 from the database 210. Furthermore, the measurement module 220 can obtain the electric power information generated by the device 290 when the electric elements A, B, and C are all “ON”. The measurement module 220 compares the electric power features with the electric power information to judge whether the device 290 with normal work of A, B, and C is abnormal.

If the device 290 is abnormal and all electric elements A, B, and C are “ON”, the judgment module 230 for example records that the anomaly time of each of the electric elements A, B, and C is once. If the device 290 is not abnormal, the judgment module 230 does not record the anomaly time. If the electric elements A and B are “ON” and C is “OFF”, the judgment module 230 records that the anomaly time of each of the electric elements A and B is once when the device 290 is abnormal. However, the anomaly time of the electric element C is not recorded. The judgment module 230 may accumulate the anomaly time for each element until all combinations are finished.

Furthermore, the judgment module 230 may further judge whether the anomaly time for one electric element reaches a threshold value so as to determine whether such electric element is abnormal. For example, if the threshold value is 3, the judgment module 230 compares the total anomaly time of an electric element with the threshold value, and thus finds out which electric element is abnormal. In such a way, users may know which electric element is aging or out of work to facilitate check and repair.

Additionally, if the judgment module 230 judges that a certain electric element is “OFF” in all combinations and the device 290 is not abnormal, it can be determined that this electric element is abnormal. For example, if the electric element C is “OFF” and the judgment module 230 judges that the device 290 is not abnormal, no matter the electric elements A and B are both “ON” or “OFF”, or one of the electric elements A and B is “ON”, it means that the electric element C is the element which causes the anomaly of the device 290.

In the other hand, if the judgment module 230 judges that all electric elements in each combination are abnormal, the sensing module 280 may be used to further judge which non-electric element of the elements 292_1˜292_M causes the anomaly of the device 290. The sensing module 280 connected to the judgment module 230 is disposed in the device 290. The sensing module 280 is configured to detect non-electric features of the device 290, such as temperature or vibration, in order to generate corresponding sensing signals and send these signals to the judgment module 230. Then, the judgment module 230 can judge whether the non-electric elements are normal or abnormal based on the sensing signals and the electric power features.

For example, the device 290 is an air conditioner, and the sending module 280 is disposed in the pipeline of the device 290. When the sensing module 280 senses the temperature (e.g., temperature of the air duct) is decreasing, the judgment module 230 judges the type of the anomaly of the non-electric elements. For example, the device 290 is abnormal due to refrigerant leakage.

Furthermore, if the sensing module 280 senses that the temperature decreases slower or that the power of the electric power information is higher than that of the electric power features, the judgment module 230 judges the type of the anomaly of the non-electric elements as that the device 290 is abnormal due to the unclean of the strainer. As a result, the apparatus for detecting device anomaly in this embodiment may completely detect abnormal cases of a device, and further know which electric element or non-electric element in the device is abnormal. Therefore, the apparatus in this embodiment may accelerate the device anomaly detection and facilitate check and repair.

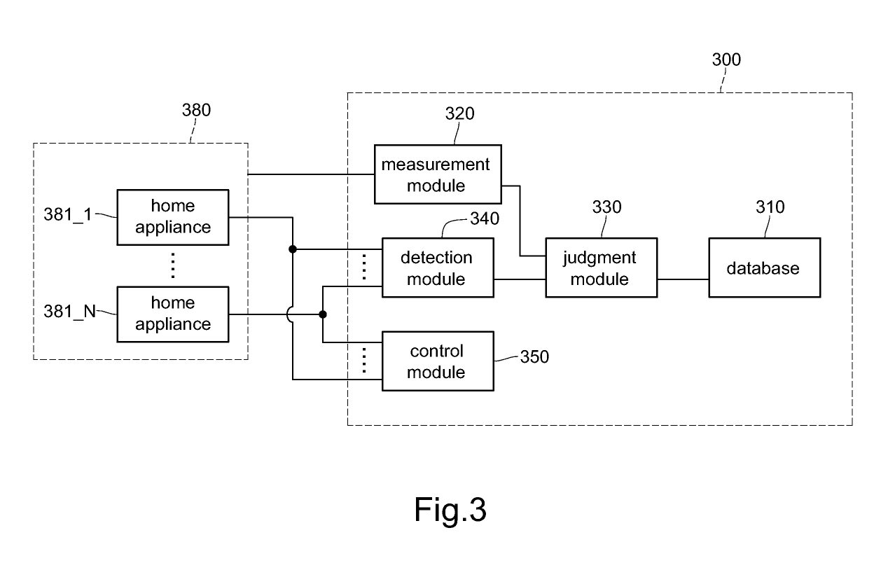

FIG. 3 is a block diagram of an apparatus for detecting device anomaly based on another embodiment of the disclosure. In this embodiment, the apparatus 300 for detecting device anomaly is configured to detect whether the device 380 is normal or abnormal. The device 380 may comprise or connect to a plurality of home appliances 381_1˜381_N. In other words, the device 380 is the assembly or group of these home appliances in a room or house. The home appliances may include microwave oven, electric rice cooker, induction cooker, and so on. The apparatus 300 includes a database 310, a measurement module 320, a judgment module 330, and a detection module 340.

The database 310 is configured to store multiple electric power features, which may refer to the normal electric power features of the different home appliances, for example, real power, reactive power, average current, relative standard deviation, and so on, but the disclosure is not limited this way. These features can be corrected or updated in process.

The measurement module 320 is configured to measure the circuits of the device 380 in order to generate electric power information. The measurement module 320 may be a power meter for measuring the total electric power consumption of the home appliances 381_1˜381_N and generating the electric power information corresponding to the total electric power consumption.

The judgment module 320 connected to the database 310 and the measurement module 320 is configured to receive the electric power information generated by the measurement module 320 and the electric power features in the database 310. Based on the electric power information and the electric power features, the judgment module 380 judges whether the device 380 is abnormal. That is, the judgment module 330 compares the electric power information with the electric power features, and thus judges whether the device 380 is abnormal.

The detection module 340 connected to the judgment module 330 is configured to detect operation states of the home appliances 381_1˜381_N in the device 380 when the device 380 is detected to be abnormal in order to generate multiple state signals. The multiple state signals are sent to the judgment module 330. In this embodiment, each home appliance is configured with a switch to generate an on-operation signal or an off-operation signal. When a home appliance is in normal operation, an on-operation signal may be generated by the switch and sent to the detection module 340, and then the detection module 340 generates for example a state signal with high logic level. When a home appliance is not in operation or in abnormal operation, an off-operation may be generated by the switch and sent to the detection module 340, and then the detection module 340 generates for example a state signal with low logic level. In an embodiment, the switch may send the on-operation signal or the off-operation signal to the detection module 340 by using wired or wireless communication.

Then, the judgment module 330 judges whether each home appliance is abnormal based on the state signal, the electric power information, and the electric power features. Particularly, if the state signal is at high logic level and the electric power information is in accordance with the electric power features, the home appliance is in normal operation, or if the state signal is at low logic level, or the state signal is at high low logic level and the electric power information is not in accordance with the electric power features, the home appliance is in abnormal operation. As a result, the apparatus 300 in the embodiment can not only know whether the device 380 is normal or abnormal, but also know which home appliance is abnormal. Therefore, the apparatus 300 can accelerate the device anomaly detection and facilitate check and repair.

In this embodiment, the database 310, the measurement module 320, the judgment module 330, and the detection module 340 can be integrated in the apparatus 300. Furthermore, the apparatus 300 can be disposed in the device 380 to facilitate the detection on the device 380.

In another embodiment, the measurement module 320 and the detection module 340 can be disposed in the device 380 while the database 310 and the judgment module 330 can be disposed in the detection apparatus 300. The measurement module 320 and the detection module 340 may sent the electric power information and the state signal to the judgment module 330 by using wired or wireless (e.g., WIFI, WIMAX, RF, PLC) communication, and thus the judgment module 330 may further judge the whole working state of the device 380 and that of each home appliance.

In addition, the apparatus 300 further comprises a control module 350 to generate multiple control signals in order to control the operation state of each home appliance in the device 380. The operation states of the home appliances 381_1˜381_N have various combinations. That is, in this embodiment, the control module 350 may sent control signals to the device 380 to control each home appliance to work or not to work. For example, if the device 380 includes 3 home appliances D, E, and F. In this case, the control module 350 sends different control signals to control the operation states of D, E, and F. The operation state combinations for the home appliances D, E, and F are shown in the table 1. For illustration, “ON” represents on-operation, and “OFF” represents off-operation.

After the control module 350 generates various operation state combinations of home appliances, the detection module 340 may detect each combination by way of polling in order to generate multiple state signals corresponding to these combinations. Then, the judgment module 330 sequentially judges whether each appliance is normal or abnormal based on corresponding state signals, electric power information, and electric power features. Therefore, a statistical chart can be established and stored in the database 310.

Furthermore, the judgment module 330 may further compare the electric power parameter in the electric power information with that in the electric power features to judge the operation state (on or off) of each home appliance. Here, the electric power parameter may be but is not limited to real power, reactive power, real power variation, reactive power variation, difference between the real power and the reactive power, the difference between the real power variation and the reactive power variation, transient current variation, and harmonic current variation. For example, the electric power parameter may refer to the difference between the real power and the reactive power, which can be obtained by a steady state analysis. In particular, the difference between the real power and the reactive power of a home appliance after a while of turn-on or turn-off is measured. When the measured difference does not vary beyond a preset threshold value, the home appliance is considered to reach the steady state. At this point, the power consumption of the home appliance, i.e., the difference between the real power and the reactive power can be achieved by using the average power at this steady state minus that at last steady state.

It is noted that it is not considerable to use only the real power as the electric power parameter to judge the operation state of a home appliance because different home appliances may consume the same or similar real power. To avoid misjudgment of operation state of a home appliance, the reactive power consumed by a non-resistive appliance is often used in the operation state judgment. The reactive power may be measured by a smart meter or a power meter. Alternatively, the reactive power may be calculated by the equations Q=\sqrt{S²−P²} and S=V×I, where S is apparent power, P is real power, Q is reactive power, V is voltage, and I is current. The difference between the real power and the reactive power is generally regarded as an electric feature for most home appliances.

If considering harmonic current variation as the electric power parameter, harmonic current variation can be obtained by measuring the harmonic current with high sample rate when turning on or turning off a home appliance. For motor-drive, pump-operated, or electronic home appliances and fluorescent lights, the odd harmonic current is apparent and thus it is suitable to be regarded as an electric power feature. The odd harmonic current variation can be calculated by performing a Fast Fourier Transform (FFT) on the measured harmonic current to the frequency domain.

As mentioned above, transient current variation can also be regarded as an electric power parameter. In this case, the measurement for measuring transient current should have a high sample rate because the turn-on or turn-off operation is done instantly. F Additionally, if the transient current variation when turning on or turning off a home appliance is fixed and can be recurred, the transient current of the home appliance may be regarded as the electric power feature. In this embodiment, signal processing or image identification is often used to identify the use of home appliances.

Based on the above, in order to identify the use of home appliances by using electric power feature, a comparison of the difference between real power and reactive power in electric power information and that in the electric power feature may be performed. If the power comparison cannot identify the usage, another comparison on harmonic current variation may be performed. Alternatively, the comparison on transient current may be performed. However, the disclosure is not limited to this way.

In addition, the electric power information used by the judgment module 330 is the sum of the electric power information for each normal home appliance. The total electric power information is used to compare with the electric power features to judge whether the home appliances are abnormal.

For example, when the control module 350 controls the home appliances D, E, and F to be “ON”, state signals received by the judgment module 330 are all at high logic level, for example, H, H, and H. Then, the judgment 330 can obtain the electric power features corresponding to each operation state combination for the home appliances from the database 310. Furthermore, the measurement module 320 can obtain the electric power information generated by the device 380 when the home appliances are all “ON”. The measurement module 320 compares the electric power features with the electric power information to judge whether the device 380 with D, E, and F in normal operation is abnormal.

If the device 380 is abnormal and all home appliances D, E, and F are “ON”, the judgment module 330 records that the anomaly time of D, E, and F is once. If the device 380 is not abnormal, the judgment module 330 does not record the anomaly time. If the device 380 is abnormal and the home appliances D and E are “ON” and F is “OFF”, the judgment module 330 records that the anomaly time of electric elements D and E is once. However, the anomaly time of the home appliance F is not recorded. The judgment module 330 may accumulate the anomaly time for each home appliance until all combinations are finished.

Furthermore, the judgment module 330 may further judge whether the anomaly time for each home appliance reaches a threshold value so as to determine whether the home appliance is abnormal. For example, if the threshold value is 3, the judgment module 330 compares the total anomaly time of each home appliance with the threshold value, and thus finds out which home appliance is abnormal. In such a way, users may know which home appliance is abnormal to facilitate check and repair.

Additionally, if the judgment module 330 judges that a certain home appliance is “OFF” in all combinations and the device 380 is not abnormal, it can be determined that this home appliance is abnormal. For example, if the home appliance F is “OFF” and the judgment module 330 judges that the device 380 is not abnormal, no matter the home appliances D and E are both “ON” or “OFF”, or one of the D and E is “ON”, it means that the home appliance F is the element which causes the anomaly of the device 380.

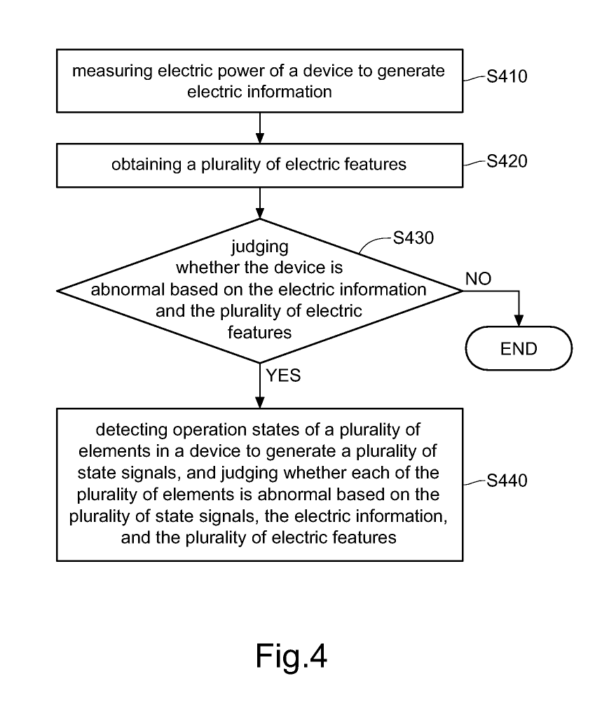

Based on the above embodiment, a method for detecting device anomaly can be concluded. FIG. 4 is a flowchart of a method for detecting device anomaly based on an embodiment of the disclosure. In the step S410, electric power of the device is measured to generate electric power information. In the step S420, multiple electric power features are obtained. In the step S430, based on the electric power information and the multiple electric power features, it is judged whether the device is abnormal.

If it is judged that the device is abnormal, the method goes to the step S440. In the step S440, operation states of multiple elements in the device are detected to generate multiple state signals, and it is judged whether each element is abnormal based on the state signals, the electric power information and the multiple electric characteristics. In the other hand, if it is judged that the device is not abnormal, the detection flow ends. In this embodiment, the multiple electric power features include real power, reactive power, average current, relative standard deviation and so on.

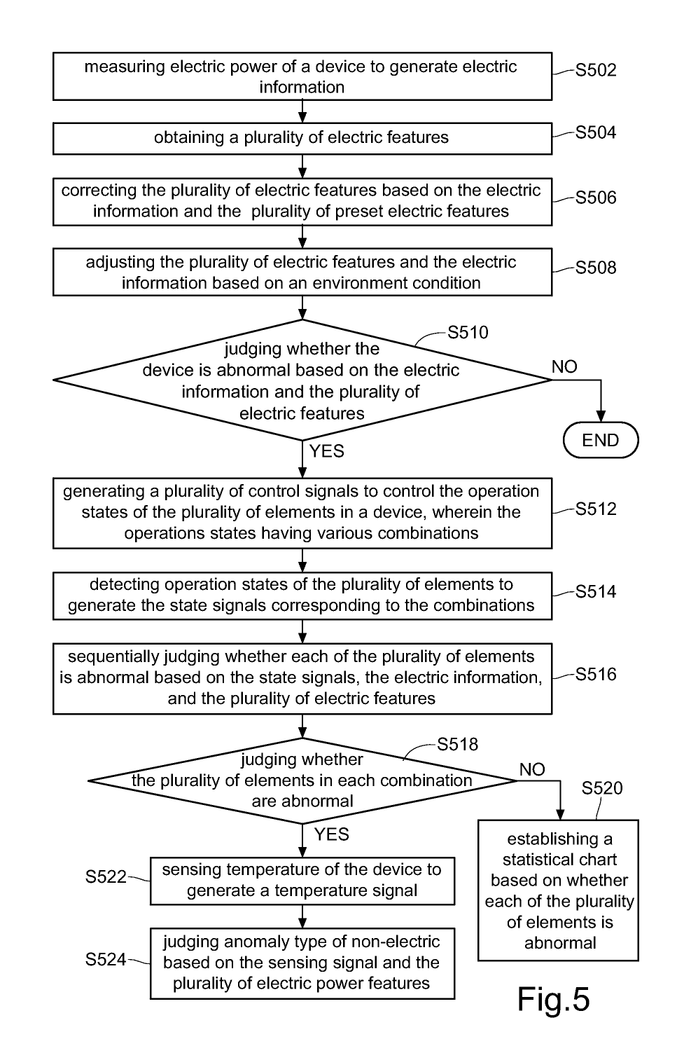

FIG. 5 is flowchart of a method for detecting device anomaly based on another embodiment of the disclosure. In the step S502, electric power of the device is measured to generate electric power information. In the step S504, multiple electric power features are obtained. In the step S506, the electric power features are corrected based on the electric power information and the preset electric power features. In the step S508, the electric power information and the electric power features are adjusted based on an environment condition. In the step S510, it is judged whether the device is abnormal based on the electric power information and the electric power features. If the device is detected to be normal, the detection flow ends.

Alternatively, if the device is detected to be abnormal, the method goes to the step S512. In the step S512, multiple control signals are generated to control operation states of all elements in the device. The operation states have various combinations. In the step S514, the operation states of the elements are detected to generate state signals corresponding to the combinations. Moreover, the operation states may be detected by way of polling. In the step S516, it is judged whether each element is abnormal based on the control signals, the electric power information and the electric power features. In the step S518, it is judged whether elements in each combination are all abnormal. If elements in each combination are all normal, the method goes to the step S520, in which a statistical chart is established based on operation state of each element.

If it is judged that elements in each combination are abnormal, the method goes to the step S522. In the step S522, the non-electric power information of the device (e.g., temperature at different locations in the device) is sensed to generate a sensing signal. In the step S524, the anomaly type of the non-electric element is judged based on the sensing signal and the electric power features. In this embodiment, the electric power features comprise real power, reactive power, average current, relative standard deviation, and so on. The environment condition mentioned in the step S508 includes an ambient temperature or a variable voltage.

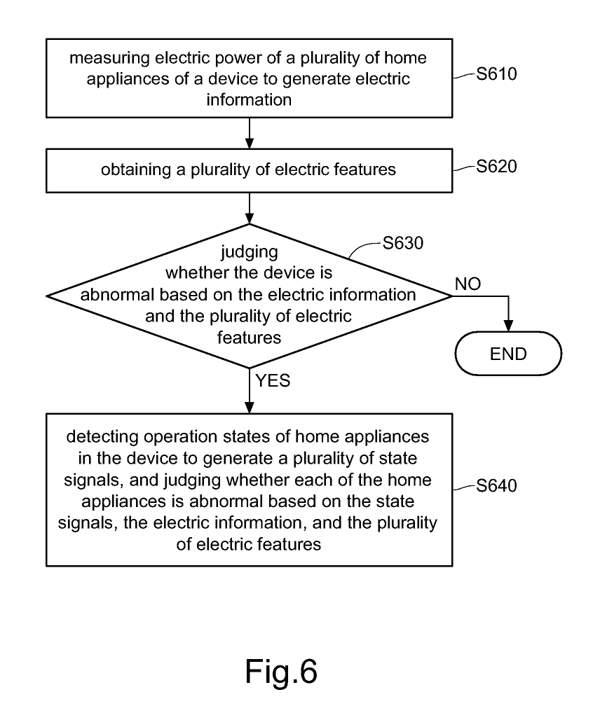

FIG. 6 is flowchart of a method for detecting device anomaly based on another embodiment of the disclosure. In the step S610, electric power of multiple home appliances in the device is measured to generate electric power information. The electric power information may be the total electric power consumption of the home appliances. In the step S620, multiple electric power features are obtained. In the step S630, it is judged whether the device is abnormal based on the electric power information and the electric power features.

If it is judged that the device is abnormal, the method goes to the step S640. In the step S640, operation states of the home appliances in the device are detected to generate multiple state signals, and it is judged whether each home appliance is abnormal based on the state signals, the electric power information, and the electric power features. In the other hand, if it is judged that the device is normal, the detection flow ends.

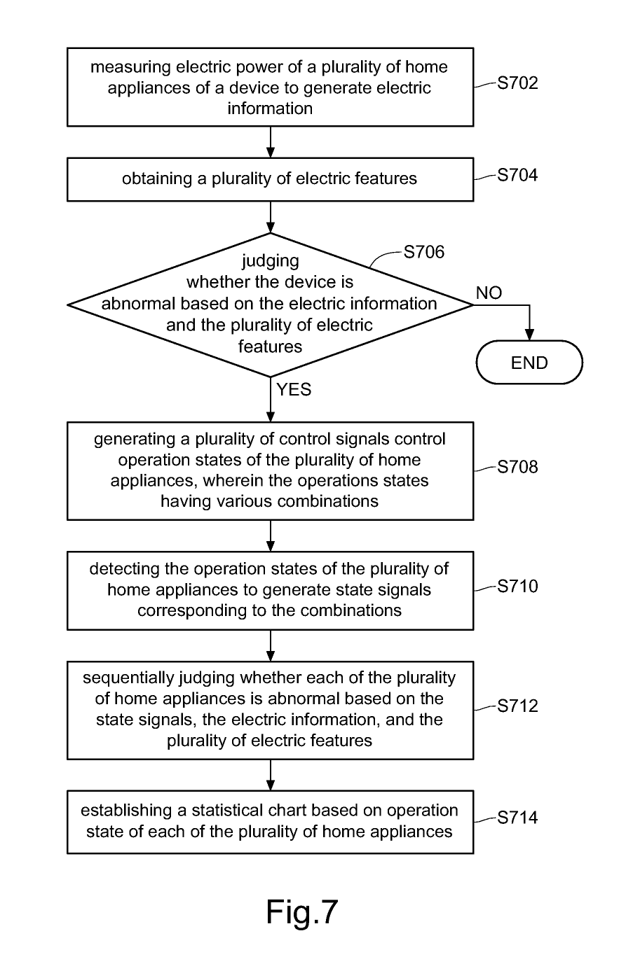

FIG. 7 is a flowchart of a method for detecting device anomaly based on another embodiment of the disclosure. In the step S702, electric power of multiple home appliances in the device is measured to generate electric power information. The electric power information may be total electric power consumption of the home appliances. In the step S704, multiple electric power features are obtained. In the step S706, it is judged whether the device is abnormal based on the electric power information and the electric power features. If it is judged that the device is not abnormal, the detection flow ends.

Alternatively, if it is judged that the device is abnormal, the method goes to the step S708. In the step S708, multiple control signals are generated to control operation states of the home appliances. The operation states of the home appliances have various combinations. In the step S710, operation states of the home appliances are detected to generate state signals corresponding to the combinations. The operation states may be detected by way of polling. In the step S712, it is judged whether each home appliance is abnormal based on the state signals, the electric power information, and the electric power features. Further in the step S712, the electric power parameter in the electric power information is compared with that in the electric power features to judge the operation state (on or off) of each home appliance. Here, the electric power parameter may be but is not limited to real power, reactive power, real power variation, reactive power variation, difference between the real power and the reactive power, the difference between the real power variation and the reactive power variation, transient current variation, and harmonic current variation. In the step S714, a statistical chart is established based on operation state of each element.

The method and apparatus for detecting device anomaly compare the electric power information measured by a measurement module with the electric power features in order to judge whether the device is abnormal. If the device is abnormal, it is judged which element (electric element or non-electric element) or home appliance in the device is abnormal. As a result, the device anomaly detection may be performed completely on the device and its elements. In addition, misjudgment of device anomaly may be reduced based on the correction and adjustment on the electric power information and the electric power features, the operation state combinations of the elements, and the sensing module. Furthermore, it can be correctly judged which electric, non-electric element, or home appliance is abnormal. Therefore, the method and apparatus for detecting device anomaly can accelerate the device anomaly detection and thus facilitate check and repair.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to activate others skilled in the art to utilize the disclosure and various embodiments and with various modifications as are suited to the particular use contemplated. Alternative embodiments will become apparent to those skilled in the art to which the present disclosure pertains without departing from its spirit and scope. Accordingly, the scope of the present disclosure is defined by the appended claims rather than the foregoing description and the exemplary embodiments described therein.

What is claimed is:

1. An apparatus for detecting device anomaly, comprising:
a database configured to store a plurality of electric power features;
a measurement module configured to measure electric power of a device to generate electric power information;
a judgment module connected to the database and the measurement module, configured to judge whether the device is abnormal based on the plurality of electric power features and the electric power information; and
a detection module connected to the judgment module, configured to detect operation states of a plurality of elements in the device to generate a plurality of state signals to the judgment module;
wherein, the judgment module further judges whether each element of the plurality of elements is abnormal based on the plurality of state signals, the electric power information, and the plurality of electric power features.

2. The apparatus based on claim 1, the plurality of electric power features comprise real power, reactive power, average current, and relative standard deviation.

3. The apparatus based on claim 1, further comprising:
a correction module connected to the measurement module and the database, configured to receive the electric power information and the plurality of electric power features, and to correct the plurality of electric power features based on the electric power information and the plurality of electric power features preset in the database; and
an adjustment module connected to the database, configured to adjust the plurality of electric power features and the electric power information based on an environment condition.

4. The apparatus based on claim 3, wherein the environment condition includes ambient temperature or variable voltage.

5. The apparatus based on claim 1, wherein the plurality of elements are electric elements.

6. The apparatus based on claim 1, the detection module detects the operation states of the plurality of elements are abnormal by way of polling to generate the plurality of state signals.

7. The apparatus based on claim 1, further comprising:
a control module configured to generate a plurality of control signals to control operation states of the plurality of elements, wherein the operation states having various combinations;
wherein, the detection module generates the plurality of state signals corresponding to the combinations based on the operation states of the plurality of elements, the judgment module sequentially judges whether each element is abnormal based on the plurality of state signals, the electric power information, and the electric power features, and a statistical chart is established and stored in the database.

8. The apparatus based on claim 7, wherein if the judgment module judges the plurality of elements in each combination are abnormal and the device further comprises a plurality of non-electric elements, the apparatus further comprising:
a sensing module connected to the judgment module and configured in the device, configured to sense non-electric power information of the device to generate a sensing signal and send the sensing signal to the judgment module;
wherein, the judgment module further judges whether the plurality of non-electric elements are abnormal based on the sensing signal and the electric power features.

9. The apparatus based on claim 1, wherein the database, the measurement module, the detection module, and the judgment module are disposed on the apparatus.

10. The apparatus based on claim 1, the measurement module and the detection module are disposed on the device, the measurement module and the detection module communicate the electric power information and the plurality of state signals in wired or wireless ways.

11. A method for detecting device anomaly, comprising:
measuring electric power of a device to generate electric power information;
obtaining a plurality of electric power features;
judging whether the device is abnormal based on the electric power information and the plurality of electric power features; and
if it is judged that the device is abnormal, detecting operation states of a plurality of elements of the device to generate a plurality of state signals, and judging whether each element of the plurality of elements is abnormal based on the electric power information and the plurality of electric power features.

12. The method based on claim 11, wherein the electric power features includes real power, reactive power, average current, and relative standard deviation.

13. The method based on claim 11, further comprising:
correcting the plurality of electric power features based on the electric power information and the plurality of preset electric power features; and
adjusting the plurality of electric power features and the electric power information based on an environment condition.

14. The method based on claim 13, wherein the environment condition comprises ambient temperature or variable voltage.

15. The method based on claim 11, wherein the plurality of elements are electric elements.

16. The method based on claim 11, wherein the operation states of the plurality of elements are detected by way of polling.

17. The method based on claim 11, wherein the step of detecting operation states of a plurality of elements of the device to generate a plurality of state signals, and judging whether each element of the plurality of elements is abnormal based on the electric power information and the plurality of electric power features, comprising:
generating a plurality of control signals to control the operation states of the plurality of elements, wherein the operation states having various combinations;
detecting the operation states of the plurality of elements to generate the plurality of control signals corresponding to the combinations;
sequentially judging whether each element of the plurality of elements is abnormal based on the state signals, the electric power information, and the plurality of electric power features;
judging whether the plurality of elements in each combination are abnormal; and
if it is judged that the plurality of elements in each combination are normal, establishing a statistical chart.

18. The method based on claim 17, wherein the device further comprising a plurality of non-electric elements, and after the step of judging whether the plurality of elements in each combination is abnormal, the method further comprising:
if it is judged that the plurality of elements in each combination is abnormal, sensing non-electric power information of the device to generate a sensing signal; and
judging whether the plurality of non-electric elements are abnormal based on the sensing signal and the electric power features.

19. An apparatus for detecting device anomaly, comprising:
a database configured to store a plurality of electric power features;
a measurement module configured to measure electric power of a plurality of home appliances in a device to generate electric power information;
a judgment module connected to the database and the measurement module, configured to detect whether the plurality of home appliances in the device is abnormal based on the electric power features and the electric information; and
a detection module connected to the judgment module, configured to detect operation states of the plurality of home appliances in the device to generate a plurality of state signals when the judgment module judges that the device is abnormal;
wherein, the judgment module further judges whether each of the plurality of home appliances is abnormal based on the plurality of state signals, the electric information, and the electric power features.

20. The apparatus based on claim 19, the operation states of the plurality of home appliances are detected by way of polling to sequentially generate the plurality of state signals.

21. The apparatus based on claim 19, further comprising:
a control module configured to generate a plurality of control signals to control the operation states of the plurality of home appliances, wherein the operation states having various combinations;
wherein, the detection module detects the operation states of the plurality of home appliances to generate the plurality of state signals corresponding to the combinations, the judgment module sequentially judges whether each of the plurality home appliances is abnormal based on the plurality of state signals, the electric information, and the plurality of electric power features, and a statistical chart is established and stored in the database.

22. The apparatus based on claim 19, the judgment module further judges operation state of each of the plurality home appliances by comparing electric power parameter in the electric power information with that in the electric power features.

23. The apparatus based on claim 22, wherein the electric power parameter comprises real power, reactive power, real power variation, reactive power variation, difference between the real power and the reactive power, the difference between the real power variation and the reactive power variation, transient current variation, and harmonic current variation.

24. The apparatus based on claim 19, wherein the database, the measurement module, the detection module and the judgment module are disposed on the apparatus.

25. The apparatus based on claim 19, wherein the measurement module and the detection module are disposed on the device, and the measurement module and the detection module communicate the electric power information and the plurality of state signals in wired or wireless ways.

26. The apparatus based on claim 19, wherein the measurement module is a power meter, and the electric information is the total electric power consumption of the plurality of home appliances.

27. The apparatus based on claim 19, wherein the plurality of home appliances is connected to the device.

28. A method for detecting device anomaly, comprising:
measuring electric power of a plurality of home appliances in a device to generate electric information;
obtaining a plurality of electric power features;
judging whether the plurality of home appliances are abnormal based on the electric information and the plurality of electric power features; and
if it is judged that the device is abnormal, detecting operation states of the plurality of home appliances to generate a plurality of state signals, and judging whether each of the plurality of home appliances is abnormal based on the plurality of state signals, the electric information, and the plurality of electric features.

29. The method based on claim 28, wherein the operation states of the plurality of home appliances are detected by way of polling.

30. The method based on claim 28, wherein the step of detecting operation states of the plurality of home appliances to generate a plurality of state signals, and judging whether each of the plurality of home appliances is abnormal based on the plurality of state signals, the electric information, and the plurality of electric features comprises:
generating a plurality of control signals to control the operation states of the plurality of home appliances, wherein the operation states having various combinations;
detecting the operation states of the plurality of home appliances to generate the plurality of state signals corresponding to the combinations;
sequentially judging whether each of the plurality of home appliances is abnormal based on the plurality of state signals, the electric information, and the plurality of electric features; and
establishing a statistical chart based on whether each of the plurality of home appliances is abnormal.

31. The method based on claim 30, wherein the step of sequentially judging whether each of the plurality of home appliances is abnormal based on the plurality of state signals, the electric information, and the plurality of electric features comprises: judging operation state of each of the plurality of home appliances by comparing electric power parameter in the electric power information with that in the electric power features.

32. The method based on claim 31, wherein the electric power parameter comprises real power, reactive power, real power variation, reactive power variation, difference between the real power and the reactive power, the difference between the real power variation and the reactive power variation, transient current variation, and harmonic current variation.

33. The method based on claim 28, the electric information is the total electric power consumption of the plurality of home appliances.
